(19) United States
(12) Patent Application Publication
(10) Pub. No.: US 2013/0153266 A1
(43) Pub. Date: Jun. 20, 2013

(54) PRINTED CIRCUIT BOARD AND METHOD OF MANUFACTURING THE SAME

(71) Applicant: Samsung Electro-Mechanics Co., Ltd., Suwon (KR)

(72) Inventors: Jin Gul Hyun, Suwon (KR); Jin Gu Kim, Suwon (KR); Young Do Kweon, Suwon (KR); Hyung Jin Jeon, Suwon (KR)

(73) Assignee: Samsung Electro-Mechanics Co., Ltd., Suwon (KR)

(21) Appl. No.: 13/719,036

(22) Filed: Dec. 18, 2012

(30) Foreign Application Priority Data
Dec. 19, 2011 (KR) 10-2011-0137179
Dec. 14, 2012 (KR) 10-2012-0146564

(51) Int. Cl. H05K 1/02; H05K 3/02

(52) U.S. Cl. CPC H05K 1/0296; H05K 3/02
USPC 174/250; 427/97.3

(57) ABSTRACT

Disclosed herein is a printed circuit board, including: a base substrate; at least one circuit pattern formed on the base substrate; at least one dummy pattern formed on the base substrate; and an insulating layer formed on the circuit pattern and the dummy pattern, wherein a distance between adjacent patterns to each other among the circuit patterns and the dummy patterns meets the following Equation 1.

$$D \leq \frac{T 2}{T 1} \times \frac{200}{1.2} \qquad [ Equation 1 ]$$

(Where D represents a distance between adjacent patterns to each other among the circuit patterns and the dummy patterns, T1 represents a thickness of the circuit pattern or the dummy pattern, and T2 represents a maximum thickness of the insulating layer formed on the circuit pattern or the dummy pattern.)

### CROSS REFERENCE TO RELATED APPLICATION

This application claims the benefit of Korean Patent Application No. 10-2011-0137179, filed on Dec. 19, 2011, entitled “Printed Circuit Board And Method Of Manufacturing a Printed Circuit Board,” Korean Patent Application No. 10-2012-0146564, filed on December 14, entitled “PRINTED CIRCUIT BOARD AND METHOD OF MANUFACTURING THE SAME”, which are hereby incorporated by reference in its entirety into this application.

### BACKGROUND OF THE INVENTION

1. Technical Field

The present invention relates to a printed circuit board and a method of manufacturing the same.

2. Description of the Related Art

A printed circuit board (PCB) serves to electrically connect mounted parts with one another through wiring patterns formed on insulating members, such as a phenol resin insulating plate, an epoxy resin insulating plate, or the like, and mechanically fix parts while supplying power, or the like. An example of the printed circuit board may include a one-side PCB in which wirings are formed on only one surface of an insulating substrate, and a double-side PCB in which wirings are formed on both sides, and a multi layered board (MLB) on which wires are formed in multiple layers. Here, at the time of forming the printed circuit board, it is important to ensure planarization of an insulating layer so as to form the reliable wiring patterns. In order to uniformly distribute the insulating layer, a spin on glass method has been used. However, even though the insulating layer is formed by the spin on glass method, it is difficult to ensure the planarization of the insulating layer by a step between the wiring patterns and a space in which the wiring patterns are not formed.

Further, in order to ensure the planarization of the insulating layer, a method of forming dummy patterns in an empty space in which the wiring patterns are not formed has been used (Korean Patent No. 10-0290477). However, the method of forming dummy patterns has also a limitation in ensuring the planarization of the insulating layer.

### SUMMARY OF THE INVENTION

The present invention has been made in an effort to provide a printed circuit board having a planarized insulating layer and a method of manufacturing the same.

Further, the present invention has been made in an effort to provide a printed circuit board and a method of manufacturing the same capable of reducing a crosstalk phenomenon.

In addition, the present invention has been made in an effort to provide a printed circuit board and a method of manufacturing the same capable of controlling an impedance value of a circuit pattern.

According to a preferred embodiment of the present invention, there is provided a printed circuit board, including: a base substrate; at least one circuit pattern formed on the base substrate; at least one dummy pattern formed on the base substrate; and an insulating layer formed on the circuit pattern and the dummy pattern, wherein a distance between adjacent patterns to each other among the circuit patterns and the dummy patterns meets the following Equation 1.

$$D \leq \frac{T 2}{T 1} \times \frac{200}{1.2} \qquad [ Equation 1 ]$$

(Where D represents a distance between adjacent patterns to each other among the circuit patterns and the dummy patterns, T1 represents a thickness of the circuit pattern or the dummy pattern, and T2 represents a maximum thickness of the insulating layer formed on the circuit pattern or the dummy pattern.)

A difference between the maximum thickness and a minimum thickness of the insulating layer may be 3 μm or less.

The thickness of the insulating layer may be 100 μm or less.

The base substrate may be an organic substrate or an organic composite substrate.

The printed circuit board may further include: a build up layer formed on or beneath the base substrate and including at least one circuit pattern and at least one insulating layer.

According to another preferred embodiment of the present invention, there is provided a printed circuit board, including: a base substrate including a first region and a second region; at least one first circuit pattern formed on the base substrate; at least one dummy pattern formed on the base substrate; an insulating layer formed on the first circuit pattern and the dummy pattern; and at least one second circuit pattern formed on the insulating layer, wherein a distance between adjacent patterns to each other among the first circuit patterns and the dummy patterns in the first region meets the following Equation 2, a distance between adjacent patterns to each other among the first circuit patterns and the dummy patterns in the second region meets the following Equation 3, and a minimum height of the insulating layer formed in the first region is formed to be larger than a maximum height of the insulating layer formed in the second region.

$$\begin{matrix}D 1 \leq \frac{T 2}{T 1} \times \frac{200}{1.2} & [ Equation 2 ] \\ D 2 > \frac{T 2}{T 1} \times \frac{200}{1.2} & [ Equation 3 ]\end{matrix}$$

(Where D1 represents a distance between adjacent patterns to each other among the first circuit patterns and the dummy patterns in the first region, D2 represents a distance between adjacent patterns to each other among the first circuit patterns and the dummy patterns in the first region, T1 represents a thickness of the first circuit pattern or the dummy pattern, and T2 represents a maximum thickness of the insulating layer formed on the first circuit pattern or the dummy pattern.)

A difference between the maximum height and the minimum height of the insulating layer in the first region may be 3 μm or less.

The thickness of the insulating layer may be 100 μm or less.

The base substrate may be an organic substrate or an organic composite substrate.

According to still another preferred embodiment of the present invention, there is provided a method of manufacturing a printed circuit board, comprising: preparing a base substrate; forming at least one circuit pattern and at least one dummy pattern on the base substrate; and forming an insulating layer on the circuit pattern and the dummy pattern by a slit die coating method, wherein a distance between adjacent patterns to each other among the circuit patterns and the dummy patterns meets the following Equation 1.

$$D \leq \frac{T 2}{T 1} \times \frac{200}{1.2} \qquad [ Equation 1 ]$$

(Where D represents a distance between adjacent patterns to each other among the circuit patterns and the dummy patterns, T1 represents a thickness of the circuit pattern or the dummy pattern, and T2 represents a maximum thickness of the insulating layer formed on the circuit pattern or the dummy pattern.)

In the forming of the insulating layer, a difference between a maximum height and a minimum height of the insulating layer may be formed to be 3 μm or less.

In the forming of the insulating layer, the thickness of the insulating layer may be 100 μm or less.

The base substrate may be an organic substrate or an organic composite substrate.

The method of manufacturing a printed circuit board may further include: after the forming of the insulating layer, forming a build up layer including at least one circuit pattern and at least one insulating layer on at least one of a lower portion of the base substrate and an upper portion of the insulating layer.

According to still yet another preferred embodiment of the present invention, there is provided a method of manufacturing printed circuit board, including: preparing a base substrate including a first region and a second region; forming at least one first circuit pattern and at least one dummy pattern on the base substrate; forming an insulating layer on the first circuit pattern and the dummy pattern by a slit die coating method; and forming at least one second circuit pattern on the insulating layer, wherein a distance between adjacent patterns to each other among the first circuit patterns and the dummy patterns in the first region meets the following Equation 2, a distance between adjacent patterns to each other among the first circuit patterns and the dummy patterns in the second region meets the following Equation 3, and a minimum height of the insulating layer formed in the first region is formed to be larger than a maximum height of the insulating layer formed in the second region.

$$\begin{matrix}D 1 \leq \frac{T 2}{T 1} \times \frac{200}{1.2} & [ Equation 2 ] \\ D 2 > \frac{T 2}{T 1} \times \frac{200}{1.2} & [ Equation 3 ]\end{matrix}$$

(Where D1 represents a distance between adjacent patterns to each other among the first circuit patterns and the dummy patterns in the first region, D2 represents a distance between adjacent patterns to each other among the first circuit patterns and the dummy patterns in the first region, T1 represents a thickness of the first circuit pattern or the dummy pattern, and T2 is a maximum thickness formed on the first circuit pattern or the dummy pattern.)

In the forming of the insulating layer, the insulating layer may be formed in the first region so that a difference between a maximum height and a minimum height of the insulating layer is 3 μm or less.

In the forming of the insulating layer, the thickness of the insulating layer may be 100 μm or less.

The base substrate may be an organic substrate or an organic composite substrate.

### BRIEF DESCRIPTION OF THE DRAWINGS

FIG. 1 is an exemplified diagram showing a printed circuit board according to a preferred embodiment of the present invention;

FIGS. 2 and 3 are diagrams sequentially showing a process of a method of manufacturing a printed circuit board according to a preferred embodiment of the present invention;

FIG. 4 is an exemplified diagram showing a distance between a circuit pattern and a dummy pattern of the printed circuit board according to the preferred embodiment of the present invention and an insulating layer.

FIG. 5 is an exemplified diagram showing a printed circuit board according to another preferred embodiment of the present invention.

FIG. 6 is an exemplified diagram showing a printed circuit board according to a still another preferred embodiment of the present invention.

FIGS. 7 to 9 are diagrams sequentially showing a method of manufacturing a printed circuit board according to still yet another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Hereinafter, a printed circuit board and a method of manufacturing the same according to preferred embodiments of the present invention will be described in detail with reference to the accompanying drawings.

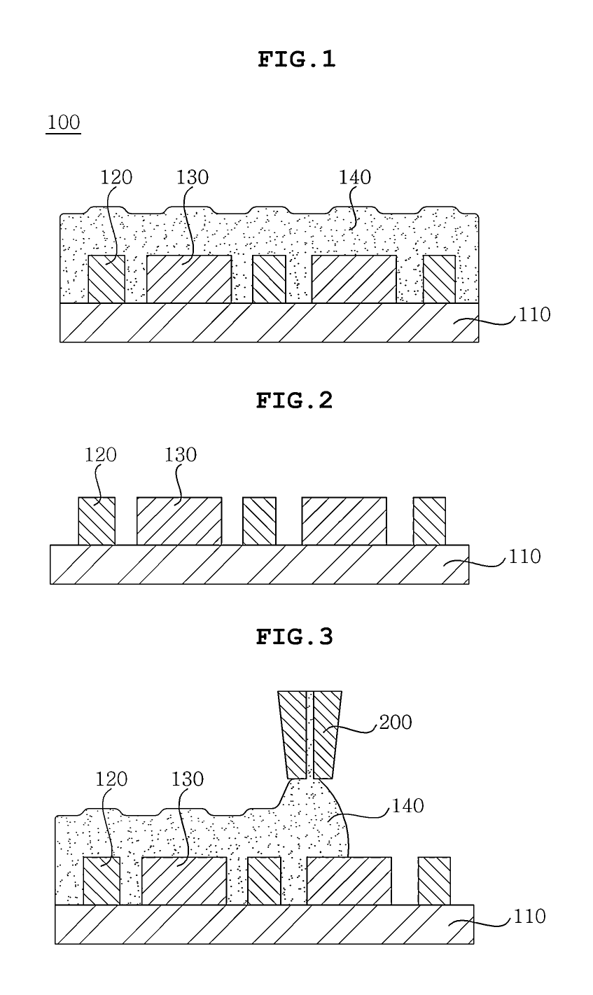

FIG. 1 is an exemplified diagram showing a printed circuit board according to the preferred embodiment of the present invention. Referring to FIG. 1, a printed circuit board 100 may include a base substrate 110, circuit patterns 120, dummy patterns 130, and an insulating layer 140.

The printed circuit board 100 may be used for mounting parts and wirings of electronic devices. The printed circuit board 100 may be a one-sided printed circuit board (PCB) forming circuit layers including the circuit patterns 120 on one surface of a base substrate 110 or a double-sided PCB having the circuit layers formed on both surfaces thereof. Alternatively, the printed circuit board 100 may be a multi layered board (MLB) on which circuit layers are formed in multiple layers.

The base substrate 110 may be made of a hard material capable of supporting a build up printed circuit board. For example, the base substrate 110 may be an organic substrate or an organic composite substrate. In addition, although not shown, a via (not shown) may be formed on the base substrate 110. When the circuit layers are formed on both surfaces of the printed circuit board 100, the via (not shown) may be formed to provide electrical signal connection between the circuit layers formed on both surfaces thereof.

The circuit pattern 120 is a conductive line formed on the base substrate 110 that transfers electrical signals according to a design pattern. That is, the circuit patterns 120 may be formed in a circuit region on the base substrate 110. The circuit pattern 120 may be made of conductive metals such as gold, silver, copper, nickel, or the like.

The dummy pattern 130 is a metal pattern formed in a dummy region on the base substrate 110. In the preferred embodiment of the present invention, the dummy region is named as a region in which the circuit patterns 120 are not formed, in the printed circuit board 100. That is, the dummy region may be a region between the circuit patterns 120.

When the insulating layer 140 is formed on the circuit pattern 120, the dummy pattern 130 may be a complementary member so as to prevent a step of the insulating layer 140 from being formed in a space between the circuit patterns 120. The dummy pattern 130 may be made of metals such as gold, silver, copper, nickel, or the like. In the preferred embodiment of the present invention, the dummy pattern 130 may be made of the same metals as the circuit pattern 120. In addition, when the circuit pattern 120 is formed, the dummy patterns 130 may be simultaneously formed. The planarized insulating layer 140 may be formed on the circuit pattern 120 by the dummy pattern 130 formed as described above.

The insulating layer 140 may be formed on the circuit pattern 120 and the dummy pattern 130. That is, the insulating layer 140 may be formed on the base substrate 110 while impregnating the circuit pattern 120 and the dummy pattern 130. The insulating layer 140 may be formed of an epoxy resin. Here, the insulating layer 140 may be formed by a slit die coating method. The slit die coating method is a method of forming an insulating layer by applying an insulating material on the base substrate 110 so that the circuit pattern 120 and the dummy pattern 130 are impregnated by using a slit die device. Here, the slit die device is a device used to form a coating layer by discharging and applying a predetermined amount of coating liquid to the substrate. The planarized insulating layer may be formed by a slit die coating method. In addition, it is possible to prevent voids from occurring when the insulating layer is formed between the circuit pattern 120 and the dummy pattern 130 by the slit die coating method. According to the preferred embodiment of the present invention, a thickness of the insulating layer 140 may be 100 μm or less. The thickness of the insulating layer 140 that may be formed by the slit die coating method using the slit die device may be 100 μm.

A step between a maximum height and a minimum height of the insulating layer 140 may be 3 μm or less. Here, the step of 3 μm may be a reference of flatness of the insulating layer 140. That is, when the step between the insulating layers 140 becomes 3 μm or less, multi-layer may be easily formed. Further, when the step between the insulating layers 140 exceeds 3 μm, defects after a post-process may occur due to a high step. For example, an align defect of a bump formed on the insulating layer 140 may occur during later processes. Alternatively, a void may be formed between the upper insulating layer 140 and the lower insulating layer 140.

Meanwhile, the preferred embodiment of the present invention describes that the circuit pattern 120, the dummy pattern 130, and the insulating layer 140 are formed on only one surface of the base substrate 110, but is only an example. Therefore, the circuit pattern 120, the dummy pattern 130, and the insulating layer 140 can be formed on both surfaces of the base substrate 110.

FIGS. 2 and 3 are flow charts showing a method of manufacturing a printed circuit board according to a preferred embodiment of the present invention.

Referring to FIG. 2, the circuit pattern 120 and the dummy pattern 130 may first be formed on the base substrate 110.

The base substrate 110 may be made of a hard material capable of supporting a build up printed circuit board. For example, the base substrate 110 may be an organic substrate or an organic composite substrate.

Further, although not illustrated, a via (not illustrated) may be formed on the base substrate 110. When the circuit layers are formed on both surfaces of the printed circuit board 100, the via (not shown) may be formed to provide electrical signal connection between the circuit layers formed on both surfaces thereof.

The circuit pattern 120 and the dummy pattern 130 may be simultaneously formed. The circuit pattern 120 is a conductive line formed on the base substrate 110 that transfers electrical signals according to a design pattern. The circuit pattern 120 may be made of conductive metals such as gold, silver, copper, nickel, or the like. The dummy pattern 130 may be formed between the empty space between the circuit patterns 120. In the preferred embodiment of the present invention, the dummy pattern 130 is formed in an empty space between the circuit patterns 120 but a position at which the dummy pattern 130 is formed is not limited thereto. That is, the dummy pattern 130 may be formed at any place in which any component including the circuit pattern 120 is not formed.

The circuit pattern 120 may be formed by a known method and the dummy pattern 130 may be formed simultaneously with forming the circuit pattern 120. For example, a plating resist patterned for forming the circuit pattern 120 and the dummy pattern may be formed on the base substrate 110. Thereafter, the plating is performed with the conductive metals by using the electroplating method and the circuit pattern 120 and the dummy pattern 130 may be simultaneously formed on the base substrate 110 by removing the plating resist.

Referring to FIG. 3, the insulating layer 140 may be formed on the circuit pattern 120 and the dummy pattern 130.

The insulating layer 140 may be formed on the base substrate 110 having the circuit pattern 120 and the dummy pattern 130 formed thereon by the slit die coating method. That is, the insulating material may be applied on the circuit pattern 120 and the dummy pattern 130 by the slit die device 200. The insulating layer 140 may be formed by discharging a predetermined amount of insulating material onto the circuit pattern 120 and the dummy pattern 130 while the slit die device 200 moves a section in which the insulating layer 140 is formed in a predetermined direction at a predetermined speed.

In this case, an insulating material may be epoxy resin. In addition, the insulating material may be discharged in a liquid state from the slit die device 200.

As such, as a liquid-phase insulating material is discharged from a slit die device 200, the insulating material may also be applied in a narrow empty space between patterns such as the circuit patterns 120 and the dummy patterns 130. Therefore, at the time of forming the insulating layer 140 by the slit die coating method, it is possible to prevent the voids from being formed in the narrow empty space between the patterns. According to the preferred embodiment of the present invention, a maximum thickness of the insulating layer 140 may be 100 μm. The thickness of the insulating layer 140 that may be formed by the slit die coating method using the slit die device may be 100 μm.

Further, the step between the maximum height and the minimum height of the insulating layer 140 may be 3 μm or less. Here, the step of 3 μm may be a reference of the flatness of the insulating layer 140. That is, when the step between the insulating layers 140 becomes 3 μm or less, the multi-layer may be easily formed. Further, when the step between the insulating layers 140 exceeds 3 μm, the defects after the post-process may occur. For example, the align defect of the bump formed on the insulating layer 140 may occur during later processes. Alternatively, a void may be formed between the upper insulating layer 140 and the lower insulating layer 140.

Further, it is possible to prevent the step between the insulating layer 140 formed on the circuit pattern 120 and the insulating layer 140 formed in the empty space from occurring by forming the dummy pattern 130 in a wide empty space between the circuit patterns 120.

Meanwhile, the preferred embodiment of the present invention describes that the circuit pattern 120, the dummy pattern 130, and the insulating layer 140 are formed on only one surface of the base substrate 110, but is only an example. Therefore, the circuit pattern 120, the dummy pattern 130, and the insulating layer 140 can be formed on both surfaces of the base substrate 110.

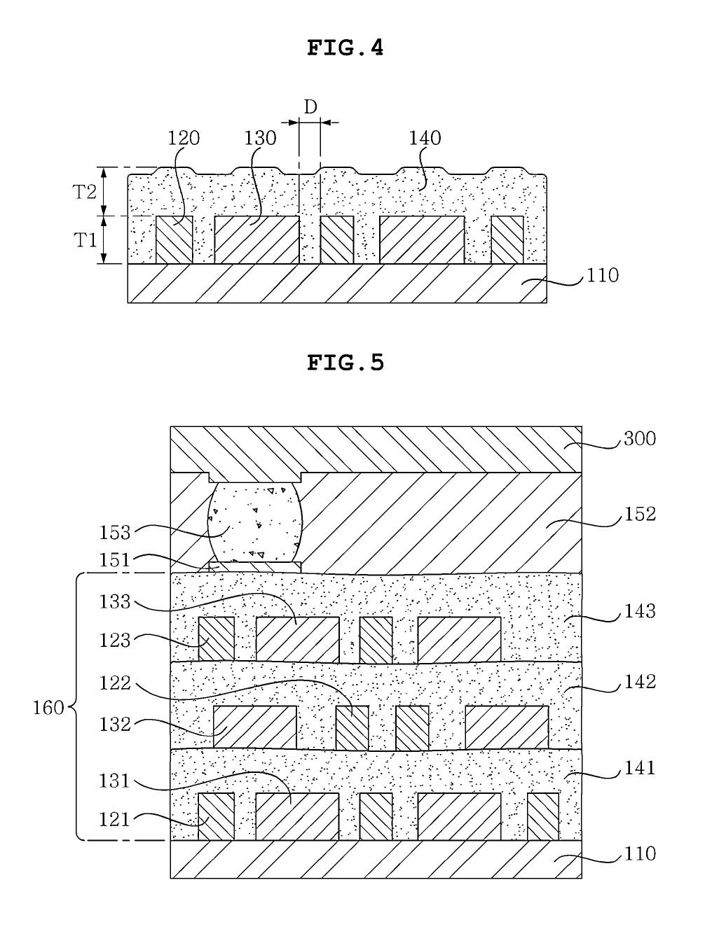

FIG. 4 is an exemplified diagram showing a distance between a circuit pattern and a dummy pattern of the printed circuit board according to the preferred embodiment of the present invention and an insulating layer.

According to the preferred embodiment of the present invention, the distance between the circuit pattern 120 and the dummy pattern 130 may be represented by the following Equation 1.

$$D \leq \frac{T 2}{T 1} \times \frac{100}{1.2} \qquad 〈 Equation 1 〉$$

Here, D is the distance between the circuit pattern 120 and the dummy pattern 130. D may be a distance between a lower portion of the circuit pattern 120 and a lower portion of the dummy pattern 130.

T1 is a thickness of the circuit pattern 120. In addition, T2 is a maximum thickness of the insulating layer 140 formed on the circuit pattern 120 or the dummy pattern 130.

The experimental results about the relationship between interval between the circuit pattern 120 and the dummy pattern 130 and the step between the insulating layers 140 may be confirmed from the following Table 1.

| T1 (μm) | T2 (μm) | D (μm) | T1/T2 * 200/1.2 | Step (μm) |
|---|---|---|---|---|
| 4.09 | 6 | 110.06 | 113.6111111 | 3 |
| 7.36 | 9 | 65.06 | 136.2962963 | 2 |
| 8.18 | 18 | 68.33 | 75.74074074 | 3 |
| 7.87 | 18 | 63.01 | 72.87037037 | 3 |
| 14.73 | 18 | 226.68 | 136.3888889 | 5.5 |
| 10.23 | 21 | 73.65 | 81.19047619 | 3 |
| 11.05 | 21 | 109.66 | 87.6984127 | 3.5 |
| 3.68 | 21 | 64.65 | 29.20634921 | 9 |

As can be appreciated from the above Table 1, when meeting Equation 1, it can be appreciated that the steps between the insulating layers 140 may be 3 μm or less. That is, when a distance between the circuit pattern 120 and the dummy pattern 130, the thickness of the circuit pattern 120 or the dummy pattern 130, and the thickness of the insulating layer 140 meet the above Equation 1, the flat insulating layer 140 may be formed.

FIG. 5 is an exemplified diagram showing a printed circuit board according to another preferred embodiment of the present invention.

Referring to FIG. 5, the printed circuit board is a printed circuit board in which a multi layered circuit layer is built up. The printed circuit board 100 may include the base substrate 110, a build up layer 160, a bump 153, and a solder resist 152.

The base substrate 110 may be made of a hard material capable of supporting the built up circuit layer. For example, the base substrate 100 may be a metal plate or an insulating member. Here, the metal plate may be a copper clad and the insulating member may be made of a composite polymer resin. Alternatively, the base substrate 110 adopts the ajinomoto build up film (ABF) to easily implement fine circuits or adopts the prepreg to thinly manufacture the printed circuit board. However, the base substrate is not limited thereto, but may be made of a hard insulating material including epoxy resin or modified epoxy resin, bisphenol A resin, epoxy-novolac resin, aramid reinforced, glass fiber reinforced, or paper reinforced epoxy resin.

In addition, although not shown, a via (not illustrated) may be formed on the base substrate 110. When the circuit layers are formed on both surfaces of the printed circuit board 100, the via (not shown) may be formed to provide the electrical signal connection between the circuit layers formed on both surfaces thereof.

The build up layer 160 may be formed on the base substrate 110. According to the preferred embodiment of the present invention, the build up layer 160 may be formed to have a structure in which the plurality of circuit patterns, the plurality of dummy patterns, and the plurality of insulating layers are stacked. According to the preferred embodiment of the present invention, the circuit pattern may include a first circuit pattern 121 to a third circuit pattern 123. Here, the circuit pattern is a conductive line formed on the base substrate 110 that transfers electrical signals according to a design pattern. The circuit pattern may be made of conductive metals such as gold, silver, copper, nickel, or the like. Further, the dummy pattern is formed in a region in which the circuit pattern is not formed and may be named as a complementary material to uniformly apply the insulating layer on the circuit pattern. According to the preferred embodiment of the present invention, the dummy pattern may include a first dummy pattern 131 to a third dummy pattern 133. The dummy pattern 130 as described above may be made of metals such as gold, silver, copper, nickel, or the like. In the preferred embodiment of the present invention, the circuit pattern and the dummy pattern are simultaneously formed and may be formed of the same material. Further, the insulating layer may be made of epoxy resin. According to the preferred embodiment of the present invention, the insulating layer may include a first insulating layer 141 to a third insulating layer 143. According to the preferred embodiment of the present invention, the insulating layer may be formed by the slit die coating method using the slit die device.

The build up layer 160 may include a first circuit pattern 121 and a first dummy pattern 131 formed on the base substrate 110. A first insulating layer 141 may be formed on the first circuit pattern 121 and the first dummy pattern 131. In this case, the first insulating layer 141 and the first dummy pattern 131 formed in the empty space in which the first circuit pattern 121 is not formed may be flatly formed by the slit die coating method.

In addition, the build up layer 160 may include a second circuit pattern 122 and a second dummy pattern 132 formed on the first insulating layer 141. The second insulating layer 142 may be formed on the second circuit pattern 122 and the second dummy pattern 132. In this case, the second insulating layer 142 and the second dummy pattern 132 formed in the empty space in which the second circuit pattern 122 is not formed may be flatly formed by the slit die coating method.

In addition, the build up layer 160 may include a third circuit pattern 123 and a third dummy pattern 133 formed on the second insulating layer 142. A third insulating layer 143 may be formed on the third circuit pattern 123 and the third dummy pattern 133. In this case, the third insulating layer 143 and the third dummy pattern 133 formed in the empty space in which the third circuit pattern 123 is not formed may be flatly formed by the slit die coating method.

As such, the build up layer 160 may be formed so that the dummy patterns formed on each layer and the insulating layers of each layer by the slit die coating method are flattened. That is, the dummy pattern and the build up layer 160 formed by using the slit die coating method according to the preferred embodiment of the present invention may be formed so that the uppermost insulating layer is also flattened regardless of the number of layers of the stacked insulating layers.

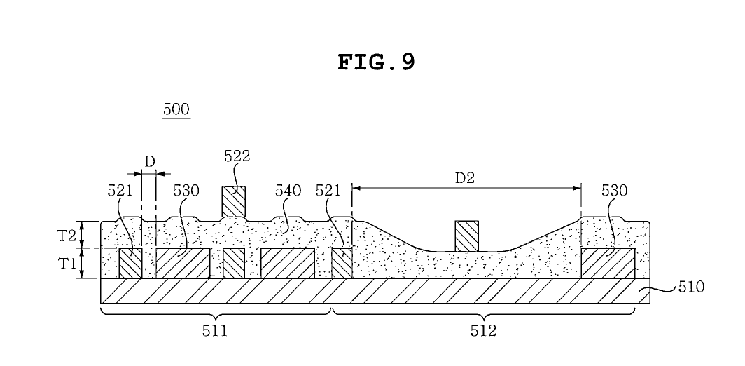

A mounting pad 151 may be formed on the build up layer 160. The mounting pad 151 may be called a terminal for being connected with the external device such as a semiconductor chip 300 to be mounted on the printed circuit board 100. FIG. 8 shows that the mounting pad 151 is formed on a third insulating layer 143 so as not to be connected with any of the first circuit pattern 121 to the third circuit patterns 123. However, the mounting pad 151 may be electrically connected with the first circuit pattern 121 to the third circuit pattern 123 through vias (not shown) by a design of those skilled in the art.

The bump 153 may be formed on the mounting pad 151. The bump 153 is to electrically connect the printed circuit board 100 with the semiconductor chip 300 through the mounting pad 151. The bump 153 may generally be formed of a solder.

The solder resist 152 may be formed on the build up layer 160. In addition, the solder resist 152 may be formed to surround the mounting pad 151 and the bump 153. The solder resist 152 is formed at an outermost portion of the printed circuit board 100 so as to protect the circuit pattern 120, or the like, from soldering and other external environments.

Meanwhile, the preferred embodiment of the present invention describes that the build up layer 160 is formed on only one surface of the base substrate, but is only an example and therefore, the build up layer 160 can be formed on both surface of the base substrate 110.

As such, at the time of forming the build up layer 160, the first insulating layer 141 to the third insulating layer 143 are each formed flatly, thereby preventing the align defect of the bump 153 from occurring when the bump 153 is formed later. Further, at the time of forming the build up layer 160, it is possible to prevent the void from being formed between the first insulating layer 141 to the third insulating layer 143.

The printed circuit board and the method of manufacturing the same according to the preferred embodiment of the present invention simultaneously apply the dummy pattern formed in the space in which the circuit patterns are not formed and formed so as to meet Equation 1 and the slit die coating method used to form the insulating layer, thereby forming the planarized insulating layer having the small step. In addition, the printed circuit board and the method of manufacturing the same according to the preferred embodiment of the present invention can improve the reliability of the printed circuit board by forming the planarized insulating layer.

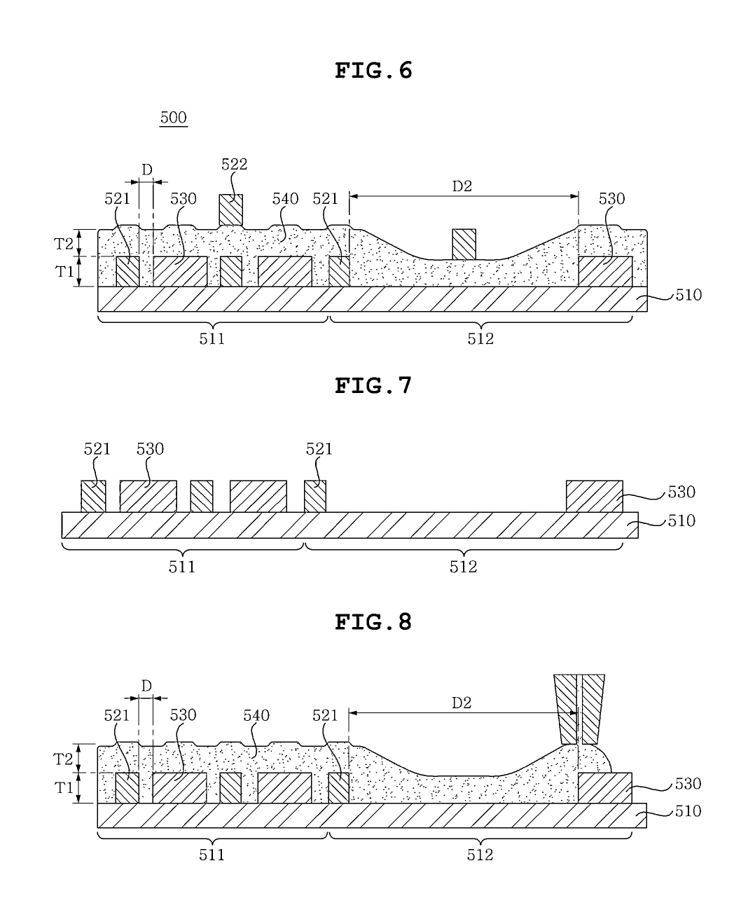

FIG. 6 is an exemplified diagram showing a printed circuit board according to a still another preferred embodiment of the present invention.

Referring to FIG. 6, a printed circuit board 500 may include a base substrate 510, a first circuit pattern 521, a second circuit pattern 522, a dummy pattern 530, and an insulating layer 540.

The printed circuit board 500 may be used for components mounting and wirings of electronic devices. The printed circuit board 500 may be a single sided printed circuit board (PCB) in which a circuit layer including the first circuit pattern 521 is formed on one surface of the base substrate 510 or a double sided PCB in which circuit layers are formed on both surfaces thereof. Alternatively, the printed circuit board 500 may be a multi layer board (MLB) on which the circuit layer is formed in multi-layer

The base substrate 510 may be made of a hard material that may support the built up printed circuit board. For example, the base substrate 510 may be an organic substrate or an organic composite substrate.

Further, although not illustrated, a via (not illustrated) may be formed on the base substrate 510. When the circuit layers are formed on both surfaces of the printed circuit board 500, the via (not shown) may be formed to provide electrical signal connection between the circuit layers formed on both surfaces thereof.

The base substrate 510 may be divided into a first region 511 and a second region 512. The first region 511 may be a region in which the plurality of circuit patterns are formed at a high density. For example, the first region 511 may be a region in which input and output (I/O) bumps are formed later at a high density. The second region 512 may be a region in which the circuit pattern for wiring are formed.

The first region 511 may be a region in which the flat insulating layer 540 is formed. The first region 511 may be a region in which the flat insulating layer 140 is formed so as to prevent the align defect of the I/O bump formed later. The first region 511 may be formed so that the plurality of patterns have a narrow interval. Here, the pattern may be at least one of the first circuit pattern 521 and the dummy pattern 530.

The second region 512 may be a region in which the insulating layer 540 having a step is formed. The second region 512 may be formed so that the plurality of patterns have a wide interval.

The first circuit pattern 521 is a conductive line formed on the base substrate 510 that transfers electrical signals according to a design pattern. That is, the first circuit pattern 521 may be formed in the circuit region on the base substrate 510. The first circuit pattern 521 may be made of conductive metals such as gold, silver, copper, nickel, or the like.

The dummy pattern 530 is a metal pattern formed in the dummy region on the base substrate 510. According to the preferred embodiment of the present invention, the dummy region is named as the region in which the first circuit pattern 521 is not formed in the printed circuit board 500. That is, the dummy region may also be a region between the first circuit pattern 521 and another first circuit pattern 521. The dummy pattern 530 may be made of metals such as gold, silver, copper, nickel, and the like. According to the preferred embodiment of the present invention, the dummy pattern 530 may be made of the same metals as the first circuit pattern 521. Further, the dummy pattern 530 may be simultaneously formed when the first circuit pattern 521 is formed. The flat insulating layer 540 may be formed on the first circuit pattern 521 by the dummy pattern 530 formed as described above.

The insulating layer 540 may be formed on the first circuit pattern 521 and the dummy pattern 530. That is, the insulating layer 540 may be formed on the base substrate 510 while the first circuit pattern 521 and the dummy pattern 530 are impregnated therein. The insulating layer 540 may be formed of an epoxy resin. Here, the insulating layer 540 may be formed by the slit die coating method. The slit die coating method is a method of forming an insulating layer by applying an insulating material on the base substrate 510 so that the first circuit pattern 521 and the dummy pattern 530 are impregnated by using the slit die apparatus. Here, the slit die apparatus is an apparatus that is used to form a coating film by discharging and applying a predetermined amount of coating solution on the substrate. The flat insulating layer may be formed by the slit die coating to form the flat insulating layer. Further, it is possible to prevent the void from occurring at the time of forming the insulating layer between the first circuit pattern 521 and the dummy pattern 530 by the slit die coating. According to the preferred embodiment of the present invention, a thickness of the insulating layer 140 may be 100 μm or less. The thickness of the insulating layer 140 that may be formed by the slit die coating method using the slit die apparatus may be 100 μm

According to the preferred embodiment of the present invention, the insulating layers 540 of the first region 511 and the second region 512 may each be formed to have a different thickness or height by the interval between the first circuit pattern 521 and the dummy pattern 530.

The second circuit pattern 522 may be formed on the insulating layer 540. The second circuit pattern 522 may be made of conductive metals such as gold, silver, copper, nickel, or the like.

According to the preferred embodiment of the present invention, the interval between the first circuit pattern 521 and the dummy pattern 530 may be formed in the first region 511 to meet Equation 2.

$$D 1 \leq \frac{T 2}{T 1} \times \frac{200}{1.2} \qquad [ Equation 2 ]$$

In the above Equation 2, D1 represents a distance between the first circuit pattern 521 and the dummy pattern 530 in the first region 511. D1 represents a distance between the lower portion of the first circuit pattern 521 and the lower portion of the dummy pattern 530 in the first region 511.

T1 is a thickness of the first circuit pattern 521. Further, T2 is a maximum thickness of the insulating layer 540 that is formed on the first circuit pattern 521 or the dummy pattern 530.

As the interval between the first circuit pattern 521 and the dummy pattern 530 is small, a step between the insulating layers 540 that is formed on the first circuit pattern 521, on the dummy pattern 530, or between the first circuit pattern 521 and the dummy pattern 530 may be small. Further, it is possible to prevent the void from occurring at the time of forming the insulating layer between the first circuit pattern 521 and the dummy pattern 530 by the slit die coating.

A step between a maximum height and a minimum height of the insulating layer 540 in the first region 511 may be 3 μm or less. Here, the step of 3 μm may be a reference of the flatness of the insulating layer 540.

The relationship between the interval between the first circuit pattern 521 and the dummy pattern 530 and the step between the insulating layers 540 can be confirmed from the above Table 1.

Further, according to the preferred embodiment of the present invention, the insulating layer 540 having a step may be formed in the second region 512. The plurality of patterns formed in the second region 512 may be formed to have a wide interval. The interval between the first circuit pattern 521 and the dummy pattern 530 may be formed in the second region 512 to meet Equation 3.

$$D 2 > \frac{T 2}{T 1} \times \frac{200}{1.2} \qquad [ Equation 3 ]$$

In the above Equation 3, D2 is a distance between the first circuit pattern 521 and the dummy pattern 530 in the second region 512. D2 may be a distance between the lower portion of the first circuit pattern 521 and the lower portion of the dummy pattern 530 in the second region 512. In the second region 512, the height of the insulating layer 540 may be formed to be smaller than that of the insulating layer 540 formed on the first circuit pattern 521 or the dummy pattern 530. Further, in the second region 512, the height of the insulating layer 540 may be formed to be larger than the minimum thickness of the insulating layer 540 formed on the first circuit pattern 521 or the dummy pattern 530.

In the printed circuit board 100 according to the preferred embodiment of the present invention, the height or the thickness of the insulating layers 540 of the first region 511 and the second region 512 may be different, and therefore the second circuit patterns 522 formed in the first region 511 and the second region 512 may each be formed at a different height. That is, the second circuit pattern 522 formed in the second region 512 may be formed at a lower position than the second circuit pattern 522 formed in the first region 511. As such, as the second circuit patterns 522 are each formed at different positions, the spaced distance therebetween may be more increased than when the second circuit patterns 522 are formed horizontally. As the spaced distance is increased, it is possible to reduce the defects from occurring due to the crosstalk. Further, the thickness of the insulating layers 540 of the first region 511 and the second region 512 may be controlled by controlling the interval between the first circuit pattern 521 and the dummy pattern 530. The impedance value of the second circuit pattern 522 may also be controlled by controlling the thickness of the insulating layer 540. The impedance value of the second circuit pattern 522 is as the following Equation 4.

$${Z}_{0} = \frac{87}{\sqrt{{ɛ}_{r} + 1.41}} Ln ( \frac{5.98 H}{0.8 W + T} ) \qquad [ Equation 4 ]$$

In the above Equation 4, Z0 represents an impedance value of the second circuit pattern 522, ∈ r represents a dielectric constant of the insulating layer, W represents a width of the second circuit pattern 522, T represents a thickness of the second circuit pattern 522, and H represents a thickness of the insulating layer 540. As such, the impedance value of the second circuit pattern 522 may be changed by the thickness of the insulating layer 540, a dielectric constant of the insulating layer 540, the width of the second circuit pattern 522, and the thickness of the second circuit pattern 522. That is, the impedance value of the second circuit pattern 522 may also be controlled by controlling the thickness of the insulating layer 540.

In the printed circuit board 500, the planarization, the step, and the thickness of the insulating layer 540 may be controlled by forming the dummy pattern 530 and the insulating layer 540 using the slit die coating method. Therefore, the printed circuit board 500 may adopt both of the portion at which the planarization of the insulating layer 540 is required and the portion at which the step is required, if necessary, such that a freedom in design can be increased. In addition, it is possible to prevent the crosstalk from occurring and control the impedance value.

FIGS. 7 to 9 are flow charts showing a method of manufacturing a printed circuit board according to still yet another preferred embodiment of the present invention.

Referring to FIG. 7, the first circuit pattern 521 and the dummy pattern 530 may be first formed on the base substrate 510.

The base substrate 510 may be made of a hard material that may support the built up printed circuit board. For example, the base substrate 510 may be an organic substrate or an organic composite substrate.

Further, although not illustrated, a via (not illustrated) may be formed on the base substrate 510. When the circuit layers are formed on both surfaces of the printed circuit board 500, the via (not shown) may be formed to provide electrical signal connection between the circuit layers formed on both surfaces thereof.

Further, the base substrate 510 may be divided into the first region 511 and the second region 512. The first region 511 is a region in which the plurality of patterns are disposed to have a narrow interval and the flat insulating layer 540 is formed. Further, the second region 512 may include the plurality of patterns disposed in a wide interval so as to have a height step from the insulating layer 540.

The first circuit pattern 521 and the dummy pattern 530 may be simultaneously formed. The first circuit pattern 521 is a conductive line formed on the base substrate 510 that transfers electrical signals according to a design pattern. The first circuit pattern 521 may be made of conductive metals such as gold, silver, copper, nickel, or the like. The dummy pattern 530 may be formed in an empty space between the first circuit patterns 521. In the preferred embodiment of the present invention, the dummy pattern 530 is formed in the empty space between the first circuit patterns 521, but the position at which the dummy pattern 530 is formed is not limited thereto. That is, the dummy pattern 530 may be formed wherever any component including the first circuit pattern 521 is not formed.

According to the preferred embodiment of the present invention, in the first region 511, the first circuit pattern 521 and the dummy pattern 530 may be formed in a narrow interval. The interval between the first circuit pattern 521 and the dummy pattern 530 may be formed in the first region 511 to meet Equation 2.

$$D 1 \leq \frac{T 2}{T 1} \times \frac{200}{1.2} \qquad [ Equation 2 ]$$

In the above Equation 2, D1 represents a distance between the first circuit pattern 521 and the dummy pattern 530 in the first region 511. D1 represents a distance between the lower portion of the first circuit pattern 521 and the lower portion of the dummy pattern 530 in the first region 511.

T1 is a thickness of the first circuit pattern 521. Further, T2 is the maximum thickness of the insulating layer (540 of FIG. 8) that is formed later on the first circuit pattern 521 or the dummy pattern 530.

As the interval between the first circuit pattern 521 and the dummy pattern 530 is small, a step between the insulating layers (540 of FIG. 8) that is formed on the first circuit pattern 521, on the dummy pattern 530, or between the first circuit pattern 521 and the dummy pattern 530 may be small. Further, it is possible to prevent the void from occurring at the time of forming the insulating layer between the first circuit pattern 521 and the dummy pattern 530 by the slit die coating.

The relationship between the interval between the first circuit pattern 521 and the dummy pattern 530 and the step between the insulating layers (540 of FIG. 8) can be confirmed from the above Table 1.

In addition, the second circuit pattern 522 and the dummy pattern 530 may be formed in the second region 512 to have a wide interval. The interval between the first circuit pattern 521 and the dummy pattern 530 may be formed in the second region 512 to meet Equation 3.

$$D 2 > \frac{T 2}{T 1} \times \frac{200}{1.2} \qquad [ Equation 3 ]$$

In the above Equation 3, D2 is a distance between the first circuit pattern 521 and the dummy pattern 530 in the second region 512. D2 may be a distance between the lower portion of the first circuit pattern 521 and the lower portion of the dummy pattern 530 in the second region 512.

The first circuit pattern 521 may be formed by the known methods and the dummy pattern 530 may be formed simultaneously with forming the first circuit pattern 521. For example, a plating resist patterned to form the first circuit pattern 521 and the dummy pattern 530 may be formed on the base substrate 510. Next, plating is performed with the conductive metals by using an electroplating method and the first circuit pattern 521 and the dummy pattern 530 may be simultaneously formed on the base substrate 510 by removing the plating resist.

Referring to FIG. 8, the insulating layer 540 may be formed on the first circuit pattern 521 and the dummy pattern 530.

The insulating layer 540 may be formed on the base substrate 510 on which the first circuit pattern 521 and the dummy pattern 530 are formed, by the slit die coating method. That is, the insulating material may be applied on the first circuit pattern 521 and the dummy pattern 530 by the slit die apparatus 200. A predetermined amount of insulating material is discharged on the first circuit pattern 521 and the dummy pattern 530 while the slit die apparatus 200 moves a section in which the insulating layer 540 is formed, in a predetermined direction at a predetermined speed, thereby forming the insulating layer 540. In this case, an insulating material may be epoxy resin. Further, the insulating material may be discharged from the slit die apparatus 200 in a liquid state.

As such, as a liquid-phase insulating material is discharged from a slit die apparatus 200, the insulating material may also be applied in a narrow empty space between patterns such as the first circuit pattern 521 and the dummy pattern 530 of the first region 511. Therefore, when the insulating layer 540 is formed by the slit die method, it is possible to prevent the void from being formed in the narrow empty space between the patterns.

According to the preferred embodiment of the present invention, a thickness of the insulating layer 140 may be 100 μm or less. The thickness of the insulating layer 140 that may be formed by the slit die coating method using the slit die apparatus may be 100 μm

The step between the maximum height and the minimum height of the insulating layer 140 in the first region 511 may be 3 μm or less. Here, the step of 3 μm may be a reference of the flatness of the insulating layer 540.

Further, in the second region 512, the height of the insulating layer 540 may be formed to be smaller than that of the insulating layer 540 formed on the first circuit pattern 521 or the dummy pattern 530. Further, in the second region 512, the height of the insulating layer 540 may be formed to be larger than the minimum thickness of the insulating layer 540 formed on the first circuit pattern 521 or the dummy pattern 530.

As such, as the liquid-phase insulating material is discharged from the slit die apparatus 200, the insulating layer 540 of the second region 512 may be formed to be thinner than the first insulating layer 540. That is, the insulating layer 540 may be formed to have a step.

Referring to FIG. 9, the second circuit pattern 522 may be formed on the insulating layer 540. In this case, the second circuit pattern 522 may be formed in both of the first region 511 and the second region 512. The second circuit pattern 522 may be made of conductive metals such as gold, silver, copper, nickel, or the like. The height or the thickness of the insulating layers 540 of the first region 511 and the second region 512 may be different, and therefore the second circuit patterns 522 formed in the first region 511 and the second region 512 may each be formed at a different height. That is, the second circuit pattern 522 formed in the second region 512 may be formed at a lower position than the second circuit pattern 522 formed in the first region 511. As such, as the second circuit patterns 522 are each formed at different positions, the spaced distance therebetween may be more increased than when the second circuit patterns 522 are formed horizontally. As the spaced distance is increased, it is possible to reduce the defects from occurring due to the crosstalk. Further, the thickness of the insulating layers 540 of the first region 511 and the second region 512 may be controlled by controlling the interval between the first circuit pattern 521 and the dummy pattern 530. Further, the impedance value of the second circuit pattern 522 may be controlled according to the thickness of the insulating layer 540. The impedance value of the second circuit pattern 522 is as the following Equation 4.

$${Z}_{0} = \frac{87}{\sqrt{{ɛ}_{r} + 1.41}} Ln ( \frac{5.98 H}{0.8 W + T} ) \qquad [ Equation 4 ]$$

In the above Equation 4, Z0 represents an impedance value of the second circuit pattern 522, ∈ r represents a dielectric constant of the insulating layer 540, W represents a width of the second circuit pattern 522, T represents a thickness of the second circuit pattern 522, and H represents a thickness of the insulating layer 540. As such, the impedance value of the second circuit pattern 522 may be changed by the thickness of the insulating layer 540, a dielectric constant of the insulating layer 540, the width of the second circuit pattern 522, and the thickness of the second circuit pattern 522. That is, the impedance value of the second circuit pattern 522 may also be controlled by controlling the thickness of the insulating layer 540.

In the preferred embodiment of the present invention, D, D1, and D2 represent the interval between the circuit pattern and the dummy pattern, which is only for convenience of description.

Therefore, the preferred embodiment of the present invention is not limited thereto. That is, D, D1, and D2 may represent a distance between adjacent patterns to each other among the circuit patterns and the dummy patterns.

Further, the preferred embodiment of the present invention describes that the circuit pattern, the dummy pattern, and the insulating layer are formed only on one surface of the base substrate, which is only an example. Therefore, the circuit pattern, the dummy pattern, and the insulating layer can be formed on both surfaces of the base substrate.

The printed circuit board and the method of manufacturing the same according to the preferred embodiments of the present invention can form the dummy patterns and the planarized insulating layer by using the slit die coating method.

The printed circuit board and the method of manufacturing the same according to the preferred embodiments of the present invention can control the thickness of the insulating layer to reduce the crosstalk phenomenon.

The printed circuit board and the method of manufacturing the same according to the preferred embodiments of the present invention can control the thickness of the insulating layer to reduce the impedance value of the circuit pattern.

Although the preferred embodiments of the present invention have been disclosed for illustrative purposes, they are for specifically explaining the present invention and thus a printed circuit board and a method of manufacturing the same are not limited thereto, but those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
at least one circuit pattern formed on the base substrate;
at least one dummy pattern formed on the base substrate; and
an insulating layer formed on the circuit pattern and the dummy pattern;
wherein a distance between adjacent patterns to each other among the circuit patterns and the dummy patterns meets the following Equation 1.
$$D \leq \frac{T 2}{T 1} \times \frac{200}{1.2} \qquad [ Equation 1 ]$$
(Where D represents a distance between adjacent patterns to each other among the circuit patterns and the dummy patterns, T1 represents a thickness of the circuit pattern or the dummy pattern, and T2 represents a maximum thickness of the insulating layer formed on the circuit pattern or the dummy pattern.)

2. The printed circuit board as set forth in claim 1, wherein a difference between the maximum thickness and a minimum thickness of the insulating layer is 3 μm or less.

3. The printed circuit board as set forth in claim 1, wherein the thickness of the insulating layer is 100 μm or less.

4. The printed circuit board as set forth in claim 1, wherein the base substrate is an organic substrate or an organic composite substrate.

5. The printed circuit board as set forth in claim 1, further comprising:
a build up layer formed on or beneath the base substrate and including at least one circuit pattern and at least one insulating layer.

6. A printed circuit board, comprising:
a base substrate including a first region and a second region;
at least one first circuit pattern formed on the base substrate;
at least one dummy pattern formed on the base substrate;
an insulating layer formed on the first circuit pattern and the dummy pattern; and
at least one second circuit pattern formed on the insulating layer,
wherein in interval between adjacent patterns to each other among the first circuit patterns and the dummy patterns in the first region meets the following Equation 2,
a distance between adjacent patterns to each other among the first circuit patterns and the dummy patterns in the second region meets the following Equation 3, and
a minimum height of the insulating layer formed in the first region is formed to be larger than a maximum height of the insulating layer formed in the second region.
$$\begin{matrix}D 1 \leq \frac{T 2}{T 1} \times \frac{200}{1.2} & [ Equation 2 ] \\ D 2 > \frac{T 2}{T 1} \times \frac{200}{1.2} & [ Equation 3 ]\end{matrix}$$
(Where D1 represents a distance between adjacent patterns to each other among the first circuit patterns and the dummy patterns in the first region, D2 represents a distance between adjacent patterns to each other among the first circuit patterns and the dummy patterns in the first region, T1 represents a thickness of the first circuit pattern or the dummy pattern, and T2 represents a maximum thickness of the insulating layer formed on the first circuit pattern or the dummy pattern.)

7. The printed circuit board as set forth in claim 6, wherein a difference between the maximum height and the minimum height of the insulating layer in the first region is 3 μm or less.

8. The printed circuit board as set forth in claim 1, wherein the thickness of the insulating layer is 100 μm or less.

9. The printed circuit board as set forth in claim 6, wherein the base substrate is an organic substrate or an organic composite substrate.

10. A method of manufacturing a printed circuit board, comprising:
preparing a base substrate;
forming at least one circuit pattern and at least one dummy pattern on the base substrate; and
forming an insulating layer on the circuit pattern and the dummy pattern by a slit die coating method,
wherein a distance between adjacent patterns to each other among the circuit patterns and the dummy patterns meets the following Equation 1.
$$D \leq \frac{T 2}{T 1} \times \frac{200}{1.2} \qquad [ Equation 1 ]$$
(Where D represents a distance between adjacent patterns to each other among the circuit patterns and the dummy patterns, T1 represents a thickness of the circuit pattern or the dummy pattern, and T2 represents a maximum thickness of the insulating layer formed on the circuit pattern or the dummy pattern.)

11. The method as set forth in claim 10, wherein in the forming of the insulating layer, a difference between a maximum height and a minimum height of the insulating layer is formed to be 3 μm or less.

12. The method as set forth in claim 10, wherein in the forming of the insulating layer, the thickness of the insulating layer is 100 μm or less.

13. The method as set forth in claim 10, wherein the base substrate is an organic substrate or an organic composite substrate.

14. The method as set forth in claim 10, further comprising: after the forming of the insulating layer, forming a build up layer including at least one circuit pattern and at least one insulating layer on at least one of a lower portion of the base substrate and an upper portion of the insulating layer.

15. A method of manufacturing printed circuit board, comprising:
preparing a base substrate including a first region and a second region;
forming at least one first circuit pattern and at least one dummy pattern on the base substrate;
forming an insulating layer on the first circuit pattern and the dummy pattern by a slit die coating method; and
forming at least one second circuit pattern on the insulating layer,
wherein a distance between adjacent patterns to each other among the first circuit patterns and the dummy patterns in the first region meets the following Equation 2,
a distance between adjacent patterns to each other among the first circuit patterns and the dummy patterns in the second region meets the following Equation 3, and
a minimum height of the insulating layer formed in the first region is formed to be larger than a maximum height of the insulating layer formed in the second region.
$$\begin{matrix}D 1 \leq \frac{T 2}{T 1} \times \frac{200}{1.2} & [ Equation 2 ] \\ D 2 > \frac{T 2}{T 1} \times \frac{200}{1.2} & [ Equation 3 ]\end{matrix}$$
(Where D1 represents a distance between adjacent patterns to each other among the first circuit patterns and the dummy patterns in the first region, D2 represents a distance between adjacent patterns to each other among the first circuit patterns and the dummy patterns in the first region, T1 represents a thickness of the first circuit pattern or the dummy pattern, and T2 is a maximum thickness formed on the first circuit pattern or the dummy pattern.)

16. The method as set forth in claim 15, wherein in the forming of the insulating layer, the insulating layer is formed in the first region so that a difference between a maximum height and a minimum height of the insulating layer is 3 μm or less.

17. The method as set forth in claim 15, wherein in the forming of the insulating layer, the thickness of the insulating layer is 100 μm or less.

18. The method as set forth in claim 15, wherein the base substrate is an organic substrate or an organic composite substrate.
